(19) United States
(12) Patent Application Publication
(10) Pub. No.: US 2004/0115882 A1
(43) Pub. Date: Jun. 17, 2004

(54) METHOD OF MANUFACTURING FLASH MEMORY

(76) Inventors: Chih-Wei Hung, Hsin-chu City (TW); Da Sung, Hsinchu (TW); Min-San Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/249,025

(22) Filed: Mar. 11, 2003

(30) Foreign Application Priority Data
Dec. 12, 2002 (TW) 91135950

(51) Int. Cl. H01L 21/336

(52) U.S. Cl. 438/257

(57) ABSTRACT

A method of manufacturing a flash memory is provided. A semiconductor substrate with a tunnel dielectric layer, a conductive layer and a mask layer sequentially formed thereon is provided. The mask layer, the conductive layer, the tunnel dielectric layer and the substrate are patterned to form a trench in the substrate. Thereafter, an insulating layer is formed inside the trench with the upper surface of the insulating layer at a level between the conductive layer and the substrate. A conductive spacer is formed on the sidewall of the mask layer and a portion of the conductive layer. The conductive layer and the conductive spacer together form a floating gate. The mask layer is removed and then an inter-gate dielectric layer is formed over the floating gate. A control gate is formed over the substrate.

### BACKGROUND OF INVENTION

1. Field of Invention

The present invention relates to a method of manufacturing a flash memory. More particularly, the present invention relates to a method of manufacturing a flash memory with a self-aligned floating gate.

2. Description of Related Art

Flash memory is a data storage device with data having the capacity to be accessed, read out or erased multiples of times. Furthermore, stored data will not be deleted even if power to the device is cut off. With these advantages, flash memory is one of the most widely adopted memory devices inside a personal computer and electronic equipment.

A typical flash memory device has a stack gate structure with a tunneling oxide layer, a floating gate for holding electric charges, an oxide/nitride/oxide (ONO) dielectric layer and a polysilicon control gate for controlling the access of data. To program data into or erase data from the flash memory device, appropriate voltages are applied to the source terminal, the drain terminal and the control gate so that electrons are injected into the polysilicon floating gate or pulled out of the polysilicon floating gate.

In general, the two common electron injection mode used in a flash memory device includes channel hot electron injection (CHEI) and Fowler-Nordheim (F-N) tunneling mode. Moreover, mode of programming data into or erasing data from the flash memory device also varies according to the electron injection or the pullout mode.

In the operation of flash memory, the operating voltage can be lower if the gate-coupling ratio (GCR) between the floating gate and the control gate is larger. Typically, the lower the operating voltage, the higher will be the operating speed and performance of the flash memory. The gate coupling ratio can be increased by increasing the overlapping area between the floating gate and the control gate, reducing the thickness of the dielectric layer between the floating gate and the control gate and increasing the dielectric constant (k) of the dielectric layer between the floating gate and the control gate.

However, as the level of integration continues to increase, size of each flash memory device must be reduced accordingly. Each memory cell can become smaller by reducing the gate length of each memory cell and the bit line separation. Yet, the reduction in gate length will reduce the overall channel length underneath the tunneling oxide layer and hence easily lead to a punch through between the drain terminal and the source terminal. Consequently, electrical properties of the memory cell may be seriously affected. In addition, photolithographic processes used in the fabrication of the flash memory may also cause critical dimension problems that limit the ultimate size reduction of each memory cell.

### SUMMARY OF INVENTION

Accordingly, one object of the present invention is to provide a method of manufacturing a flash memory with self-aligned floating gate. Through a floating gate structure that includes a conductive spacer on the sidewall of a mask layer and a portion of a conductive layer and the conductive layer, overlapping area between the floating gate and a control gate is increased leading to a higher coupling ratio in the device.

To achieve these and other advantages and in accordance with the purpose of the invention, as embodied and broadly described herein, the invention provides a method of manufacturing a flash memory. A semiconductor substrate with a tunnel dielectric layer, a conductive layer and a mask layer sequentially formed thereon is provided. The mask layer, the conductive layer, the tunnel dielectric layer and the substrate are patterned to form a trench in the substrate. Thereafter, an insulating layer is formed inside the trench with the upper surface of the insulating layer at a level between the conductive layer and the substrate. A conductive spacer is formed on the sidewall of the mask layer and a portion of the conductive layer. The conductive layer and the conductive spacer together form a floating gate. The mask layer is removed and then an inter-gate dielectric layer is formed over the floating gate. Finally, a control gate is formed over the substrate.

In the process of fabricating a floating gate inside the flash memory, a conductive spacer is formed on the sidewall of the mask layer and a portion of the conductive layer. A structural combination of the conductive spacer with the conductive layer to form the floating gate increases the overlapping area between the floating gate and the control gate, thereby increasing the coupling ratio of the device.

Furthermore, the conductive spacer is formed in a self-aligned process. Since the conductive spacer is formed without relying on photolithographic technique, processing step is simplified and production cost is lowered.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A to 1G are schematic cross-sectional view showing the progression of steps for manufacturing a flash memory according to one preferred embodiment of this invention.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

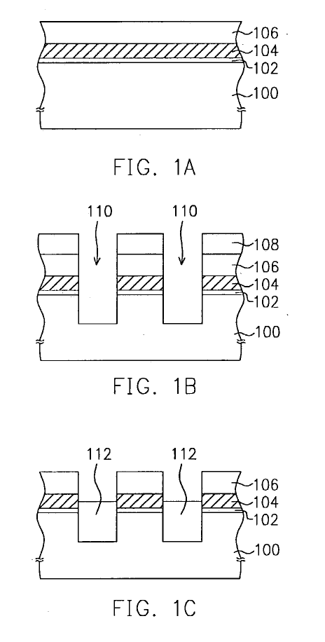

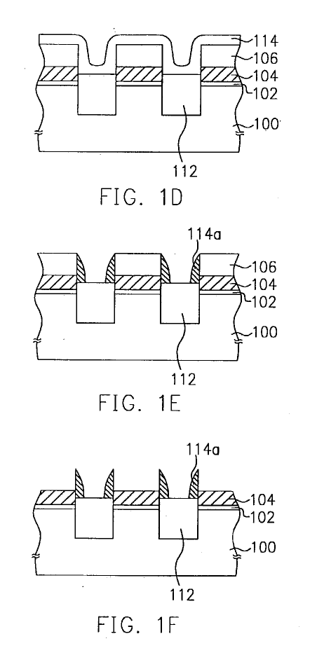

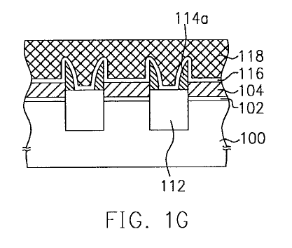

FIGS. 1A to 1G are schematic cross-sectional view showing the progression of steps for manufacturing a flash memory according to one preferred embodiment of this invention. As shown in FIG. 1A, a substrate 100 such as a silicon substrate is provided. A tunnel dielectric layer 102, a conductive layer 104 and a mask layer 106 are sequentially formed over the substrate 100.

The tunnel dielectric layer 102 having a thickness between about 50 Å to 100 Å is fabricated using a material such as silicon oxide. The tunnel dielectric layer 102 is formed, for example, by conducting a thermal oxidation or a low-pressure chemical vapor deposition (LPCVD).

The conductive layer 104 over the tunnel dielectric layer 102 is fabricated using a material such as doped polysilicon. The conductive layer 104 is formed, for example, by conducting a low-pressure chemical vapor deposition (LPCVD) using silane as a gaseous reactant to form a polysilicon layer and then implanting dopants into the polysilicon layer. The low-pressure chemical vapor deposition is carried out at a temperature between 575° C. to 650° C. and a pressure of between 0.3 to 0.6 Torr.

The mask layer 106 above the conductive layer 104 is fabricated using a material such as silicon nitride. The mask layer 106 is formed, for example, by conducting a low-pressure chemical vapor deposition (LPCVD) using dichloro-silane and ammonia as gaseous reactants. Obviously, the mask layer 106 can be fabricated using other materials as long as etching selectivity is different from a subsequently formed floating gate material.

As shown in FIG. 1B, a patterned photoresist layer 108 is formed over the mask layer 106. Using the patterned photoresist layer 108 as a mask, the mask layer 106, the conductive layer 104, the tunnel dielectric layer 102 and the substrate 100 are etched to form a trench 110 in the substrate 100.

As shown in FIG. 1C, the patterned photoresist layer 108 is removed. An insulating layer 112 is formed inside the trench 110 to serve as a device isolation structure. The upper surface of the insulating layer 112 is at a level between the upper surface of the first conductive layer 104 and the upper surface of the substrate 100. The insulating layer 112 is fabricated using a material such as silicon oxide. The insulating layer 112 is formed, for example, by conducting a chemical vapor deposition using tetra-ethyl-ortho-silicate (TEOS)/ozone as the gaseous reactants. The insulating layer 112 inside the trench 110 is formed by the following series of steps. First, an insulating material is deposited over the substrate 100 and filled the trench 110. Thereafter, the insulating material outside the trench 110 is removed in a planarization process. Lastly, a portion of the insulating material inside the trench 110 is removed so that the upper surface of the insulating layer 112 is between the first conductive layer 104 and the substrate 100. To planarize the insulating material layer, a chemical-mechanical polishing (CMP) or a back etching operation may be used. The insulating material inside the trench 110 may be removed, for example, by conducting a back etching operation.

As shown in FIG. 1D, a conductive layer 114 is formed over the substrate 100. The conductive layer 114 is fabricated using a material such as doped polysilicon. The conductive layer 114 is formed, for example, by conducting a low-pressure chemical vapor deposition (LPCVD) using silane as a gaseous reactant to form a polysilicon layer and then implanting dopants into the polysilicon layer. The low-pressure chemical vapor deposition is carried out at a temperature between 575° C. to 650° C. and a pressure of between 0.3 to 0.6 Torr.

As shown in FIG. 1E, an anisotropic etching operation is carried out to remove a portion of the conductive layer 114 and form a conductive spacer 114a on the sidewall of the mask layer 106 and the sidewall of a portion of the first conductive layer 104.

As shown in FIG. 1F, the mask layer 106 is removed. The mask layer 106 is removed, for example, by wet etching. If the mask layer 106 is a silicon nitride layer, the mask layer 106 can be removed using phosphoric acid as an etchant. After removing the mask layer 106, the exposed conductive layer 104 and the conductive spacer 114a constitute the floating gate of the flash memory.

As shown in FIG. 1G, an inter-gate dielectric layer 116 is formed over the floating gate. The inter-gate dielectric layer 116 is a composite layer such as an oxide/nitride/oxide (ONO) layer. The inter-gate dielectric layer 116 is formed, for example, by conducting a thermal oxidation to form an oxide layer and then conducting a low-pressure chemical vapor deposition (LPCVD) to form a silicon nitride layer and another oxide layer. Obviously, the inter-gate dielectric layer 116 can be a single material layer such as a silicon oxide layer or a composite material layer such as an oxide/nitride layer.

A conductive layer 118 is formed over the substrate 100 to serve as a control gate. Thereafter, processes for completing the fabrication of the flash memory are carried out. Since conventional steps are used, detail description is omitted.

In the aforementioned embodiment, the conductive spacer 114a formed on the sidewall of the mask layer 106 and a portion of the conductive layer 106 together with the conductive layer increases the overlapping area between the floating gate and the control gate. Furthermore, the conductive spacer 114a hangs over the isolation structure and thus increases the overlapping area between the floating gate and the control gate without increasing area occupation of the memory cell. Hence, the coupling ratio as well as the level of integration of the device is increased.

Moreover, the conductive spacer 114a is formed in a self-aligned process without relying on photolithographic technique. Therefore, processing step is simplified and production cost is lowered.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method of manufacturing a flash memory, comprising the steps of:
providing a substrate, wherein the substrate has a tunnel dielectric layer, a conductive layer and a mask layer sequentially formed thereon;
patterning the mask layer, the conductive layer, the tunnel dielectric layer and the substrate to form a trench in the substrate;
forming an insulating layer inside the trench such that the upper surface of the insulating layer is at a level between the conductive layer and the substrate;
forming a conductive spacer on the sidewall of the mask layer and part of the conductive layer, wherein the conductive layer and the conductive spacer together constitute a floating gate;
removing the mask layer;
forming an inter-gate dielectric layer over the floating gate; and
forming a control gate over the substrate.

2. The method of claim 1, wherein the inter-gate dielectric layer is a composite layer including an oxide/nitride/oxide layer.

3. The method of claim 1, wherein the step of forming the conductive spacer on the sidewalls of the mask layer and part of the conductive layer includes the sub-steps of:
forming a conductive material layer over the substrate; and
conducting an anisotropic etching process to remove a portion of the conductive material layer so as to form the conductive spacer on the sidewalls of the mask layer and part of the conductive layer.

4. The method of claim 1, wherein the step of forming the insulating layer inside the trench with the upper surface of the insulating layer between the conductive layer and the substrate includes the sub-steps of:
forming an insulating material layer over the substrate and filling the trench;
planarizing the insulating material layer to expose the mask layer; and
removing a portion of the insulating material layer so that the upper surface of the insulating material layer inside the trench is between the conductive layer and the substrate.

5. The method of claim 4, wherein the method of planarizing the insulating material layer includes chemical-mechanical polishing.

6. The method of claim 4, wherein the method of removing a portion of the insulating material layer include etching back method.

7. The method of claim 1, wherein the method of forming the insulating layer includes conducting a chemical vapor deposition using tetra-ethyl-ortho-silicate (TEOS)/ozone as reactive gases to form a silicon oxide layer.

8. The method of claim 1, wherein the method of removing the mask layer includes wet etching.

9. The method of claim 1, wherein the material constituting the mask layer includes silicon nitride.

10. The method of claim 6, wherein the mask layer is removed by using an etchant including phosphoric acid.

11. A method of manufacturing a flash memory, comprising the steps of:
providing a substrate, wherein the substrate has a tunnel dielectric layer, a conductive layer and a mask layer sequentially formed thereon;
patterning the mask layer, the conductive layer, the tunnel dielectric layer and the substrate to form a trench in the substrate;
forming an insulating material layer over the substrate and filling the trench;
planarizing the insulating material layer to expose the mask layer;
removing a portion of the insulating material layer so that the upper surface of the insulating material layer inside the trench is between the conductive layer and the substrate;
forming a second conductive layer over the substrate;
conducting an anisotropic etching operation to remove a portion of the second conductive layer so that a conductive spacer is formed on the sidewalls of the mask layer and part of the first conductive layer, wherein the first conductive layer and the conductive spacer constitute a floating gate;
removing the mask layer;
forming an inter-gate dielectric layer over the floating gate; and
forming a control gate over the substrate.

12. The method of claim 11, wherein the inter-gate dielectric layer is a composite layer including an oxide/nitride/oxide layer.

13. The method of claim 11, wherein the method of planarizing the insulating material layer includes chemical-mechanical polishing.

14. The method of claim 11, wherein the method of removing a portion of the insulating material layer include etching back method.

15. The method of claim 11, wherein the method of forming the insulating layer includes conducting a chemical vapor deposition using tetra-ethyl-ortho-silicate (TEOS)/ozone as reactive gases to form a silicon oxide layer.

16. The method of claim 11, wherein the method of removing the mask layer includes wet etching.

17. The method of claim 16, wherein the material constituting the mask layer includes silicon nitride.

18. The method of claim 11, wherein the mask layer is removed by using an etchant such as phosphoric acid.
